(19) United States
(12) Patent Application Publication
(10) Pub. No.: US 2026/0361278 A1
(43) Pub. Date: Nov. 12, 2026

(54) DUAL POLARIZED BEAMFORMER

(71) Applicant: MEDIATEK INC., Hsinchu City (TW)

(72) Inventors: Hashem ZARE HOSEINI, Cambridge (GB); Amin MOHAMMADPOUR, Cambridge (GB)

(73) Assignee: MEDIATEK INC., Hsinchu City (TW)

(21) Appl. No.: 19/348,234

(22) Filed: Oct. 2, 2025

Related U.S. Application Data
(60) Provisional application No. 63/801,905, filed on May 8, 2025.

(51) Int. Cl. H03F 3/24; H03F 1/26

(52) U.S. Cl. CPC H03F 3/245; H03F 1/26; H03F 2200/294; H03F 2200/336; H03F 2200/451

(57) ABSTRACT

A compact radio-frequency (RF) beamforming circuit for dual-polarized antenna systems includes amplification circuits with amplifiers configured to receive RF signals via first antennas of first polarization channels and second antennas of second polarization channels. The circuit comprises first and second vector modulator VGAs having in-phase and quadrature variable gain amplifiers (I-VGAs and Q-VGAs) arranged in pairs, with each pair coupled to respective amplifiers. First summing nodes combine first signal components from the first and second I-VGAs, while second summing nodes combine second signal components from the first and second Q-VGAs. An I/Q generator is coupled to both summing nodes, functioning as both a phase shifter and combiner for processing the polarization signals. The disclosed beamforming techniques can also be applied to a transmitter.

### CROSS-REFERENCE TO RELATED APPLICATIONS

This application claims the benefit of the U.S. Provisional Application No. 63/801,905, filed May 8, 2025, which is incorporated herein by reference in its entirety.

### TECHNICAL FIELD

The present disclosure relates to a compact dual polarized beamformer.

### BACKGROUND

Beamforming in radio-frequency (RF) systems enables directional signal transmission and reception by applying phase shifts or time delays to antenna elements. To support modern communication requirements, such as polarization diversity and improved spectral efficiency, dual-polarized beamforming is often employed. These systems typically support vertical and horizontal antennas and create Linear or Circular polarizations.

However, conventional dual-polarized beamformers require multiple independent phase-shifting components for each polarization channel, including variable gain amplifiers, phase shifters which can include I/Q generators, and combiners. This results in increased area, power consumption, system complexity, and calibration overhead. There is a growing need for more compact and efficient architectures that reduce component count while maintaining polarization performance and beamforming flexibility.

### SUMMARY

An aspect of the present disclosure provides a radio-frequency (RF) beamforming circuit. The RF beamforming circuit can include amplification circuits having amplifiers configured to receive RF signals via first antennas of first polarization channels and second antennas of second polarization channels. The amplifiers each corresponds to one of the first antennas or the second antennas. The RF beamforming circuit can include first vector modulation circuits having first in-phase variable gain amplifiers (I-VGAs) and first quadrature variable gain amplifiers (Q-VGAs) arranged into pairs. Each pair of first I-VGA and first Q-VGA are coupled to a respective one of the amplifiers that correspond to the first antennas. The RF beamforming circuit can include second vector modulation circuits having second I-VGAs and second Q-VGAs arranged into pairs. Each pair of second I-VGA and second Q-VGA are coupled to a respective one of the amplifiers that correspond to the second antennas. The RF beamforming circuit can include first summing nodes coupled to the first I-VGAs and the second I-VGAs. The first summing nodes are configured to combine first signal components from the first I-VGAs and the second I-VGAs. The RF beamforming circuit can also include second summing nodes coupled to the first Q-VGAs and the second Q-VGAs. The second summing nodes are configured to combine second signal components from the first Q-VGAs and the second Q-VGAs. The RF beamforming circuit can further include an I/Q generator coupled to the first summing nodes and the second summing nodes.

In some embodiments, the I/Q generator functions as both a phase shifter for generating I/Q components and a combiner for processing the RF signals of the first polarization channels and the second polarization channels.

In some embodiments, the I/Q generator receives first outputs from the first summing nodes and second outputs from the second summing nodes, the first outputs corresponding to the RF signals received from both the first antennas and the second antennas, the second outputs corresponding to the RF signals received from both the first antennas and the second antennas.

In some embodiments, at least one of the first I-VGAs, the first Q-VGAs, the second I-VGAs, and the second Q-VGAs is configured to perform polarization gain control for the RF signals of the first polarization channels and the second polarization channels.

In some embodiments, the I/Q generator is configured to combine gain-controlled RF signals of the first polarization channels and the second polarization channels received from the first and second summing nodes.

In some embodiments, the I/Q generator is shared between the first polarization channels and the second polarization channels.

In some embodiments, the first vector modulation circuits and the second vector modulation circuits include shared inductive coils between the first polarization channels or between second polarization channels.

In some embodiments, the first summing nodes and second summing nodes are coupled between the first and second vector modulation circuits and the I/Q generator.

In some embodiments, the first and second vector modulation circuits are disposed to receive signals associated with the first polarization and second polarization, respectively, and each of the first and second vector modulation circuits including transmission lines configured to route signals to a respective one of the first summing nodes or the second summing nodes.

In some embodiments, the beamforming circuit is integrated into a transmitter and receiver system configured for full-duplex operation with the first polarization channel and second polarization channel.

Another aspect of the present disclosure provides a RF beamforming system. The RF beamforming system can include first antennas and second antennas configured to receive RF signals of first polarization channels and second polarization channels, respectively. The RF beamforming system can also include amplification circuits configured to amplify the received RF signals. The amplification circuits have amplifiers each corresponding to one of the first antennas or the second antennas. The RF beamforming system can further include a beamformer. The beamformer can include first vector modulation circuits having first in-phase variable gain amplifiers (I-VGAs) and first quadrature variable gain amplifiers (Q-VGAs) arranged into pairs. Each pair of first I-VGA and first Q-VGA are coupled to a respective one of the amplifiers that correspond to the first antennas. The beamformer can include second vector modulation circuits having second I-VGAs and second Q-VGAs arranged into pairs. Each pair of second I-VGA and second Q-VGA are coupled to a respective one of the amplifiers that correspond to the second antennas. The beamformer can include first summing nodes coupled to the first I-VGAs and the second I-VGAs. The first summing nodes are configured to combine first signal components from the first I-VGAs and the second I-VGAs. The beamformer can also include second summing nodes coupled to the first Q-VGAs and the second Q-VGAs. The second summing nodes are configured to combine second signal components from the first Q-VGAs and the second Q-VGAs. The beamformer can further include an I/Q generator coupled to the first summing nodes and the second summing nodes.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Various embodiments of this disclosure that are proposed as examples will be described in detail with reference to the following FIGURES, wherein like numerals reference like elements, and wherein:

FIG. 1 is a block diagram of an example RF transmit and/or receive system 100, in accordance with some embodiments of the present disclosure.

FIG. 2A is a circuit diagram of an example I/Q vector modulation (i.e. phase shifter) circuit that may be included in systems herein, in accordance with some embodiments of the present disclosure.

FIG. 2B is a polar graph of an example RF signal that may be modulated using the I/Q vector modulation circuit of FIG. 2A, in accordance with some embodiments of the present disclosure.

FIG. 3 is a circuit diagram of an example RF receiver system 300 that includes an I/Q generator for each signal channel, in accordance with some embodiments of the present disclosure.

FIG. 4 is a circuit diagram of an example RF receiver system 400 that includes one I/Q generator for a vertical signal channel and another I/Q generator for a horizontal signal channel, in accordance with some embodiments of the present disclosure.

FIG. 5 is a circuit diagram of an example RF receiver system 500 that includes an I/Q generator shared among the signal channels of vertical polarization and horizontal polarization, in accordance with some embodiments of the present disclosure.

FIG. 6 is a circuit diagram of an example RF transmitter system 600 that includes an I/Q generator shared among the signal channels, in accordance with some embodiments of the present disclosure.

FIG. 7 is a circuit diagram of an example RF transceiver system 700 that includes a transmitter and a receiver, in accordance with some embodiments of the present disclosure.

FIGS. 8A-8C illustrate performance simulation charts showing noise figure, voltage gain, and output phase characteristics of the compact dual-polarized beamforming phase shifter across varying polarization orientations from 0° to 90°, in accordance with some embodiments of the present disclosure.

### DETAILED DESCRIPTION

In conventional radio-frequency (RF) beamforming systems, particularly in dual-polarized architectures that utilize vector modulation-based phase shifting, separate signal channels are allocated for each polarization, and each channel is associated with a dedicated phase shifting circuit that typically includes an in-phase/quadrature (I/Q) generator (also referred to as a phase shifter in the disclosure), variable gain amplifiers (VGAs), and combiners. This redundancy not only increases the component count and system complexity but also results in excessive area and power consumption, especially when implemented in dense array environments.

Additionally, in vector modulator-based phase shifting systems, the use of a separate I/Q generator for each channel further exacerbates these issues. Each I/Q generator, often implemented with passive inductive components, occupies a large silicon footprint. When used in multi-channel systems, this results in significant layout area. Additionally, neighboring I/Q circuits may introduce channel cross-talk due to electromagnetic coupling, leading to degraded polarization isolation and requiring complex calibration schemes to mitigate such effects.

The present disclosure provides compact and efficient dual-polarized beamforming systems that integrate polarization handling within the phase shifting and gain control circuit. In some aspects, a single I/Q generator is shared across multiple polarization channels, and the phase-shifting components including VGAs and phase shifters (for generating I/Q components) are arranged to support both beamforming and polarization control. Coils within the VGAs are shared between vertical and horizontal channels, significantly reducing area usage and simplifying routing.

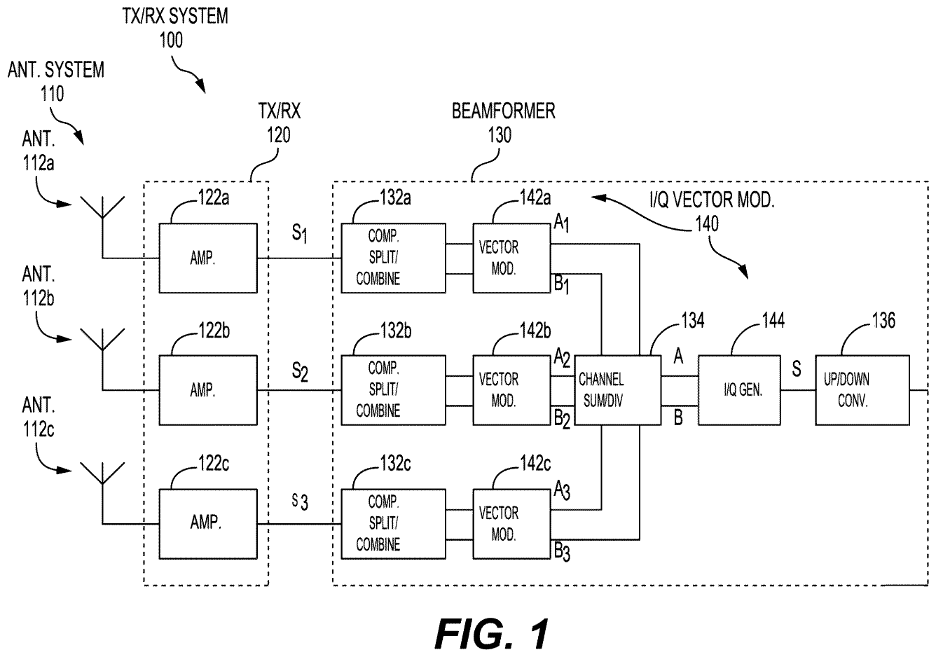

FIG. 1 is a block diagram of an example RF transmit and/or receive system 100, in accordance with some embodiments. As an example shown in FIG. 1, the system 100 may be configured to condition, beamform, and transmit and/or receive RF signals. For example, the system 100 includes an antenna system 110, a transmit and/or receive circuit 120, and a beamformer 130. In some embodiments, the antenna system 110 may be configured to transmit and/or receive RF signals, the transmit and/or receive circuit 120 may be configured to condition RF signals received and/or for transmission via the antenna system 110, and the beamformer 130 may be configured to steer RF signals received and/or transmitted via the antenna system 110. In some embodiments, the beamformer 130 may be coupled to further processing circuit operating at baseband and/or at an intermediate frequency (IF) band, such as to obtain a signal to be transmitted at RF and/or to provide a signal received at RF via the antenna system 110.

In some embodiments, components of the system 100 may be configured to operate at RF. For example, the components of the system 100 (e.g., the antenna system 110 and/or the transmit and/or the receive circuit 120) may be configured to operate in at least one frequency band within a range from 5 gigahertz (GHz) to 100 GHz, although other ranges of frequencies may be used. For instance, a single frequency band may be used for transmission and/or reception, and/or multiple frequency bands may be used for transmission and reception, respectively. Examples of frequency bands that may be used include: a frequency band having a center frequency of 10 GHZ, a frequency band having a center frequency of 30 GHZ, a frequency band having a center frequency of 50 GHz, a frequency band having a center frequency of 70 GHZ, a frequency band having a center frequency of 90 GHz, as well as other frequency bands that may be used.

In accordance with various embodiments, the system 100 may be implemented together with and/or within a wireless communication system that operates using beamforming. In some embodiments, the system 100 may be implemented in a data communication device (e.g., a 5G communication device), such as a mobile device (e.g., mobile phone, portable computer, and/or wearable device), a centralized data communication base station (e.g., a cell tower), and/or a distributed data communication network node (e.g., a decentralized cell network node). Alternatively, in some embodiments, the system 100 may be implemented in a radio detection and ranging (RADAR) system and/or a satellite communications (SATCOM) system. It should be appreciated that other implementations of the present aspects are also contemplated.

In some embodiments, components of the system 100 may be implemented using integrated circuit (IC) technology. For example, the transmit and/or receive circuit 120 and the beamformer 130 may be implemented using one or more ICs. In some embodiments, the transmit and/or receive circuit 120 and the beamformer 130 may be implemented in separate ICs, or in a single IC that integrates both. These ICs may be mounted on the same circuit board and interconnected via board-level traces. In some examples, the ICs may be disposed on different circuit boards and electrically interconnected via board-to-board connectors. In some embodiments, the antenna system 110 may be coupled to the transmit and/or receive circuit 120 via one or more cables, such as coaxial cables.

In some embodiments, the antenna system 110 may include a plurality of antennas arranged as part of a one-dimensional or two-dimensional antenna array configured for use with beamforming techniques. For example, the antenna system 110 may include a first antenna 112a, a second antenna 112b, and a third antenna 112c. These antennas may be disposed along a row, a column, or at respective positions in a two-dimensional grid. The antennas 112a-112c may be spaced at regular intervals, such as approximately one-half wavelength (2/2) at the operating frequency, to facilitate beamforming and suppress grating lobes. In some embodiments, one or more of the antennas 112a-112c may be dual-polarized to support multiple polarization modes (e.g., vertical and horizontal polarization or circular polarization). Applying phase shifts to signals transmitted and/or received by antennas 112a-112c may result in beam steering along one or more axes, depending on the array configuration. While three antennas are shown in this example, it should be appreciated that the antenna system 110 may include any suitable number of antennas.

In some embodiments, the transmit and/or receive circuit 120 may include a plurality of transmitters and/or receivers, each configured to communicate via a respective antenna of the antenna system 110. For example, the transmit and/or receive circuit 120 may include a first transmitter and/or receiver having amplification circuit 122a coupled to the first antenna 112a, a second transmitter and/or receiver having amplification circuit 122b coupled to the second antenna 112b, and a third transmitter and/or receiver having amplification circuit 122c coupled to the third antenna 112c. In this example, the amplification circuit 122a, 122b, and 122c are configured to transmit and/or receive RF signals via antennas 112a-112c, respectively. It should be appreciated that any suitable number of transmitters and/or receivers may be included, and they may be associated with antennas arranged in a one-dimensional or two-dimensional array.

In some embodiments, the system 100 may include and/or be configured as a receiver system, with the transmit and/or receive circuit 120 including receivers. Alternatively, in some embodiments, the system 100 may include and/or be configured as a transmitter system, with the transmit and/or receive circuit 120 including transmitters. Further alternatively, in some embodiments, the system 100 may include and/or be configured as a transceiver system, with the transmit and/or receive circuit 120 including both transmitters and receivers.

In some embodiments, the beamformer 130 may be configured to combine RF signals received via the antenna system 110 into a beamformed RF signal, or to distribute a beamformed RF transmit signal to individual antennas using beamforming techniques. For example, the beamformer 130 may be coupled at one end to the transmitters and/or receivers of the transmit and/or receive circuit 120 to obtain received RF signals and/or to provide RF signals for transmission via the antenna system 110. In some embodiments, the beamformer 130 may be coupled at its other end to processing circuit to provide an RF receive signal and/or to obtain an RF transmit signal to be transmitted via the antenna system 110. In some examples, each transmitter and/or receiver may be associated with a respective transmit and/or receive channel. For example, the amplification circuit of each transmitter and/or receiver may include an amplifier configured to transmit and/or receive RF signal via a respective RF antenna and associated with the respective transmit and/or receive channel.

In some embodiments, the beamformer 130 may be configured to perform a component-wise transition between the RF transmit and/or receive channels and RF signal transitioned to and/or from the channels. For example, the beamformer 130 includes component splitters and/or combiners 132a, 132b, and 132c for each RF transmit and/or receive channel. In some embodiments, received RF signals S1, S2, and S3 may be split into multiple components at the splitters 132a-132c, and/or transmitted RF signals S1, S2, and S3 may be combined from multiple components at the combiners 132a-132c. As described further herein, multiple signal components may be used for I/Q vector modulation.

In some embodiments, the beamformer 130 may include circuit configured to transition between an RF signal and multiple RF signals that are steered with respect to the RF signal. For example, the beamformer 130 includes summing and/or dividing nodes 134. In some embodiments, the summing and/or dividing nodes 134 may include a channel summing circuit configured to transition multiple RF signals associated with respective RF receive channels into an RF receive signal by summing the multiple RF signals. For example, each RF receive channel may be associated with an antenna of the antenna system 110 and a receiver of the transmit and/or receive circuit 120. Alternatively or additionally, in some embodiments, the summing and/or dividing nodes 134 may include a channel dividing circuit configured to divide an RF transmit signal into multiple RF signals associated with respective RF transmit channels. For example, each RF transmit channel may be associated with an antenna of the antenna system 110 and a transmitter of the transmit and/or receive circuit 120. In some embodiments, the channel summing and/or dividing nodes 134 are coupled between multiple transmit and/or receive channels supporting respective RF signals S1, S2, and S3, and an RF signal S. For instance, RF signals S1, S2, and S3 may be steered with respect to RF signal using beamforming, as described herein.

In some embodiments, the beamformer 130 may include an I/Q vector modulation circuit 140 configured to steer multiple RF signals with respect to an RF signal. For example, the I/Q vector modulation circuit 140 may be configured to apply a phase shift to multiple RF signals that forms a beam with respect to the RF signal, thereby performing beamforming in combination with the channel summing and/or dividing nodes 134. In some embodiments, the I/Q vector modulation circuit 140 includes multiple vector modulation circuit 142a, 142b, and 142c for each RF transmit and/or receive channel and an I/Q generator 144.

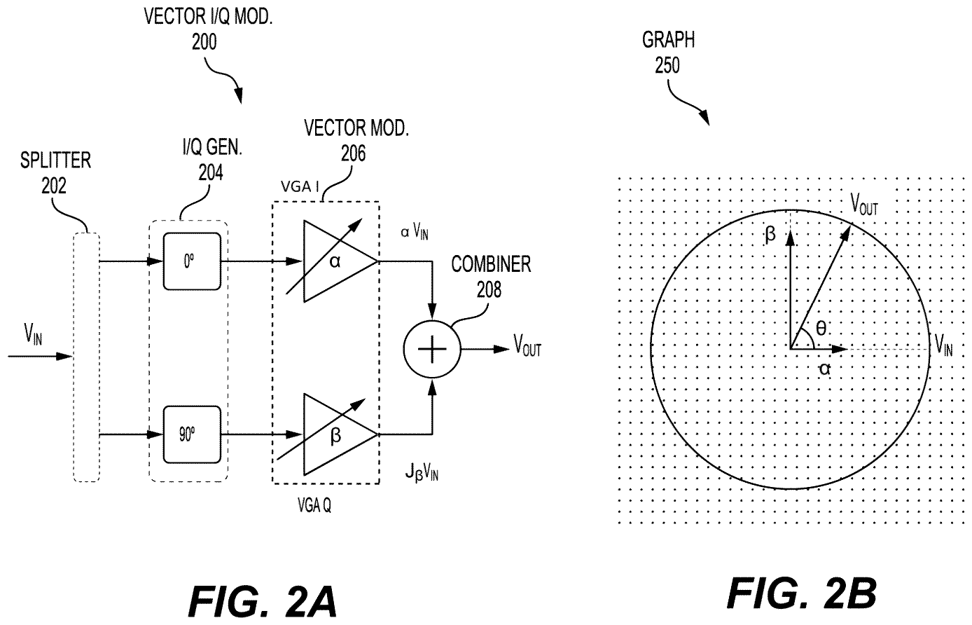

In some embodiments, the vector modulation circuit 142a, 142b and 142c may be configured to perform component-wise processing of RF signals in each RF transmit and/or receive channel. For example, the vector modulation circuit 142a is coupled to the component splitter and/or combiner 132a to receive and/or provide a first signal component A1 and a second signal component B1 of RF signal S1, the vector modulation circuit 142b is coupled to the component splitter and/or combiner 132b to receive and/or provide a first signal component A2 and a second signal component B2 of RF signal S2, and the vector modulation circuit 142c is coupled to the component splitter and/or combiner 132c to receive and/or provide a first signal component A3 and a second signal component B3 of RF signal S3. In some embodiments, the first signal components A1-A3 may correspond to the in-phase components of the respective RF signals S1-S3, and the second components B1-B3 may correspond to the quadrature components of the respective RF signals S1-S3 (e.g., 90 degrees out of phase from the in-phase components). For example, the vector modulation circuit 142a, 142b and 142c may be configured to individually adjust amplitudes of first signal components A1-A3 and to individually adjust amplitudes of second components B1, B2, and B3 as part of I/Q vector modulation, described further herein in connection with FIGS. 2A-2B.

In some embodiments, the I/Q generator 144 may be configured to perform component-wise processing of RF signal S. For example, the I/Q generator 144 may be configured to process the first component A of RF signal S as an in-phase component and the second component B of RF signal S as a quadrature component. In some embodiments, the I/Q generator 144 may be implemented using an inductive I/Q generator. Alternatively or additionally, in some embodiments, the I/Q generator 144 may be implemented using a first component (e.g., in-phase) frequency converter and a second component (e.g., quadrature) frequency converter, such as oscillator-based frequency converters.

In some embodiments, the summing and/or dividing nodes 134 may be configured to convert between a first component of an RF signal and first components of multiple RF signals, and between a second component of the RF signal and second components of multiple RF signals. For example, the summing and/or dividing nodes 134 are coupled to the vector modulation circuit 142a, 142b, and 142c to receive and/or provide the first components A1-A3 of RF signals S1-S3, respectively, as well as the second components B1-B3 of RF signals S1-S3, respectively. As shown in FIG. 1, the summing and/or dividing nodes 134 are coupled to the I/Q generator 144 to provide and/or receive a first component A and a second component B of RF signal S. In some examples, the channel summing and/or dividing nodes 134 may be configured to convert the first component A from the first components A1-A3 as a sum and/or to convert the first components A1-A3 from the first component A as a division. In some embodiments, the summing and/or dividing nodes 134 may include, for each channel, a first summing and/or dividing circuit coupled between the amplification circuit of the channel (e.g., 122a) and a first port (e.g., in-phase port) of the I/Q generator 144 to transition between the first (e.g., in-phase) component (e.g., A1) in the channel and first the component A of RF signal S, and a second summing and/or dividing circuit coupled between the amplification circuit of the channel (e.g., 122a) and a second port (e.g., quadrature port) of the I/Q generator 144 to transition between the second (e.g., quadrature) component (e.g., B1) in the channel and the second component B of RF signal S.

In some embodiments, the summing and/or dividing nodes 134 may be coupled between the amplification circuit of transmit and/or receive circuit 120 and at least a portion of I/Q vector modulation circuit 140. For example, the summing and/or dividing nodes 134 can be coupled between the amplification circuit 122a, 122b and 122c and the I/Q generator 144 of I/Q vector modulation circuit 140.

In some embodiments, the beamformer 130 may further include an up-conversion and/or down-conversion circuit 136. For example, the up-conversion and/or down-conversion circuit 136 may be configured to up-convert a transmit signal to RF for beamforming and transmission and/or to down-convert a received RF signal for further processing. According to various embodiments, the up-conversion and/or down-conversion circuit 136 may be configured to up-convert from and/or down-convert to baseband and/or an IF band, depending on the application. It should also be appreciated that some embodiments may omit the up-conversion and/or down-conversion circuit 136, such as where further upstream and/or downstream processing is performed at RF.

FIG. 2A is a circuit diagram of an example I/Q vector modulation (i.e. phase shifter) circuit that may be included in systems herein, in accordance with some embodiments of the present disclosure.

In some embodiments, the systems described herein may be configured to perform I/Q vector modulation on an RF signal to add a phase shift to the RF signal. For example, as is known from Euler's formula, S=e^{jθ}=A+jB=cos (θ)+j sin (θ), a phase shift θ may be introduced to an RF signal by splitting an RF signal S into in-phase and quadrature components A and jB and individually adjusting the amplitudes of the components. For example, where an RF signal S′ has amplitude 1 and the desired phase shift θ is 30°, A may be set to

$$\frac{√ 3}{2}$$

and B may be set to ½. In this example, when the individually adjusted components are recombined, the RF signal S′ has the complex values

$$S ’ = \frac{√ 3}{2} + j \frac{1}{2} = cos ( 30 ° ) + j sin ( 30 ° ) .$$

In some embodiments, the I/Q vector modulation as described herein may be performed on a received signal, such as to steer a plurality of received signals in a particular direction. Alternatively or additionally, the I/Q vector modulation as described herein may be performed on a signal to be transmitted, such as to steer a plurality of transmitted signals in a particular direction.

In some embodiments, the I/Q vector modulation circuit 200 may be configured to perform I/Q vector modulation on an RF signal by splitting the RF signal into first and second components, modulating the first and second components to generate in-phase and quadrature components, individually adjusting amplitudes of the in-phase and quadrature components, and combining the in-phase and quadrature components into an I/Q vector modulated RF signal. For example, the I/Q vector modulation circuit 200 includes a splitter 202, an I/Q generator 204, a vector modulation circuit 206, and a combiner 208.

In some embodiments, the I/Q generator 204 may be configured to modulate the first and second components from the splitter 202 to generate in-phase and quadrature components. For example, the I/Q generator 204 may include a 90 degree phase shifter coupled to one output of the splitter 202, such as where the splitter 202 includes a current divider. Alternatively or additionally, in some embodiments, the splitter 202 and the I/Q generator 204 may together include a 90 degree hybrid coupler and/or inductive transformer-based coupler (e.g., a passive I/Q generator) configured to receive an RF signal and split the RF signal into a first output and a second output that is 90 degrees out of phase with respect to the first output, such as where voltage signals are propagated along transmission lines. In some embodiments, the splitter 202 and the I/Q generator 204 may be configured to operate at in a narrow RF band used for transmission and/or reception by the system, although in other embodiments, wideband RF technologies may be used within the scope of the present disclosure.

In some embodiments, the vector modulation circuit 206 may be configured to individually adjust amplitudes of the in-phase and quadrature components from the I/Q generator 204. For example, the vector modulation circuit 206 may include active components such as variable gain amplifiers (VGAs) and/or passive components such as potentiometers. For instance, the VGAs may be suitable for use with voltage signals to apply individual amplitude adjustments to the in-phase and quadrature components, whereas potentiometers may be suitable for use with current signals to produce different voltages at summing and/or transimpedance amplifiers (TIAs) that convert the current signals to voltages. In some embodiments, active and/or passive components of the vector modulation circuit 206 may be configured for digital control. For example, digital control may provide high precision, such as 5 bits of amplitude control (e.g., for 32 possible amplitude levels). In some implementations, the VGAs may further be configured to perform polarization gain control, which refers to adjusting the respective gains applied to RF signals of different polarization channels (e.g., vertical and horizontal polarizations) in order to balance signal strengths, compensate for channel imbalances, or optimize performance metrics such as noise figure, linearity, and beamforming accuracy. It should be appreciated that active and/or passive components may be used as suitable for the application within the scope of the present disclosure.

In some embodiments, the combiner 208 may be configured to recombine the in-phase and quadrature components from the vector modulation circuit 206 into an I/Q vector modulated RF signal. For example, the combiner 208 may include a summing amplifier, such as where voltage signals are propagated along transmission lines, and/or a current combiner (e.g., a node at which current from parallel conductors combines to propagate in a single conductor), such as where current signals are propagated along conductors. It should be appreciated that any suitable combiner may be used in any application within the scope of the present disclosure.

It should be appreciated that, as used herein, “in-phase” and “quadrature” components of an RF signal may have any phase relationship with respect to the RF signal. For example, an in-phase component of an RF signal may be offset from the RF signal by 45 degrees and a quadrature component of the RF signal may be offset from the RF signal by −45 degrees such that the in-phase and quadrature components are 90 degrees out of phase from one another. Moreover, it should be appreciated that in-phase and quadrature components may not be exactly 90 degrees out of phase with one another, depending on the level of phase noise tolerable by the system.

FIG. 2B is a polar graph of an example RF signal that may be modulated using the I/Q vector modulation circuit 200, in accordance with some embodiments of the present disclosure.

In some embodiments, an RF signal V_{IN} may be modulated into an output V_{OUT} with an in-phase component of amplitude α and a quadrature component of amplitude β. For example, V_{IN} may be plotted at the origin of the polar graph and V_{OUT} may be plotted at coordinates (α, β). In some embodiments, the in-phase and quadrature components of the RF signal V_{IN} may be obtained by splitting the RF signal V_{IN} (e.g., using the splitter 202) and applying in-phase and quadrature modulation (e.g., using the I/Q generator 204). In this example, the amplitudes a and β may be set via individual adjustment of the in-phase and quadrature components (e.g., using the vector modulation circuit 206), and the output V_{OUT} may be generated by combining the components (e.g., using the combiner 208).

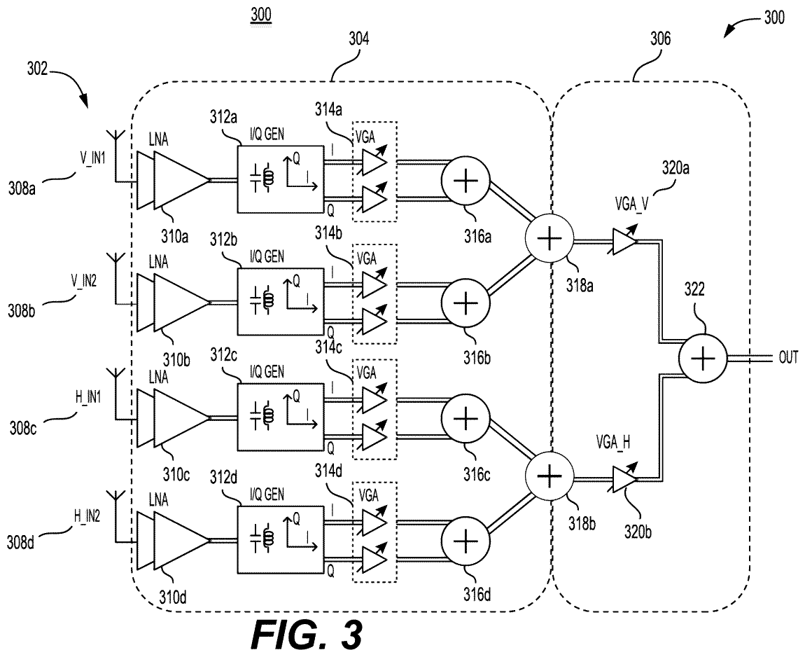

FIG. 3 is a circuit diagram of an example RF receiver system 300 that includes an I/Q generator for each signal channel, in accordance with some embodiments of the present disclosure. As shown in FIG. 3, the system 300 includes an antenna system 302, a beamforming combining section 304, and a polarization combining section 306. The system 300 employs separate signal processing channels for vertical and horizontal channel polarizations.

As an example shown in FIG. 3, the antenna system 302 includes four antennas 308a, 308b, 308c, 308d. In some embodiments, the antennas 308a and 308b are configured to receive vertically polarized signals V_IN1 and V_IN2, respectively, and the antennas 308c and 308d are configured to receive horizontally polarized signals H_IN1 and H_IN2, respectively. The polarization implemented by these antennas can include linear polarization, circular polarization, or elliptical polarization.

In some embodiments, the beamforming combining section 304 is coupled to the antenna system 302. Each signal channel within the beamforming combining section 304 includes a respective I/Q generator 312a, 312b, 312c, or 312d, each configured to process signals in a manner consistent with the embodiment illustrated in FIGS. 2A-2B. Each I/Q generator 312a, 312b, 312c, and 312d is coupled to a corresponding antenna 308a, 308b, 308c, and 308d via a respective low-noise amplifier (LNA) 310a, 310b, 310c, and 310d. The I/Q generators 312a, 312b, 312c, and 312d are further coupled to a respective vector modulation circuit 314a, 314b, 314c, and 314d. Similar to FIG. 2A, each vector modulation circuit 314a, 314b, 314c and 314d may include active components such as variable gain amplifiers (VGAs) and/or passive components such as potentiometers. The I and Q components output from each I/Q generator are processed through a respective vector modulation circuit 314a, 314b, 314c, and 314d. The resulting signals from the vertical polarization channels are combined by first vertical channel summing nodes 316a and 316b, respectively, and the signals from the horizontal polarization channels are combined by first horizontal channel summing nodes 316c and 316d, respectively. Thereafter, signals from the vertical polarization channels (V_IN1 and V_IN2) are combined by a second vertical channel summing node 318a, and signals from the horizontal polarization channels (H_IN1 and H_IN2) are combined by a second horizontal channel summing node 318b. The resulting outputs are then provided to the polarization combining section 306.

In some embodiments, the polarization combining section includes a vertical polarization variable gain amplifier (VGA_V) 320a configured to control the amplitude of the vertical polarization signals and a horizontal polarization variable gain amplifier (VGA_H) 320b configured to control the amplitude of the horizontal polarization signals. The outputs of VGA_V 320a and VGA_H 320b are then combined by a third summing node 322 to generate a single output signal.

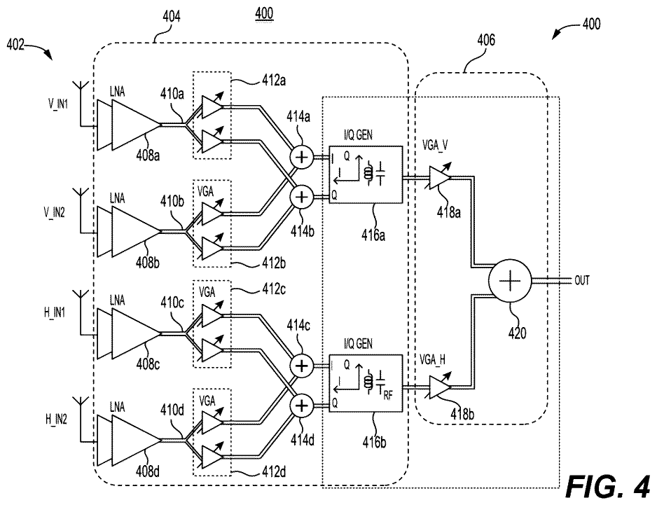

FIG. 4 is a circuit diagram of an example RF receiver system 400 that includes one I/Q generator for a vertical signal channel and another I/Q generator for a horizontal signal channel, in accordance with some embodiments of the present disclosure. As shown in FIG. 4, the system 400 includes an antenna system 402, a beamforming combining section 404, and a polarization combining section 406. Similar to FIG. 3, the system 400 employs separate signal processing channels for vertical and horizontal channel polarizations, and the antenna system 402 is configured to receive vertically polarized signals V_IN1 and V_IN2 and horizontally polarized signals H_IN1 and H_IN2.

In some embodiments, the beamforming combining section 404 is coupled to the antenna system 402. In the beamforming combining section 404, splitters 410a, 410b, 410c, and 410d are coupled to the antenna system 402 via low-noise amplifiers (LNAs) 408a, 408b, 408c, and 408d to receive RF signals. Each of the splitters 410a, 410b, 410c, and 410d is configured to generate corresponding first component and second component (corresponding to I and Q components) of the received RF signal. The first and second components are then provided to vector modulation circuits 412a, 412b, 412c, and 412d, which are configured to adjust the amplitude of the signals. The amplitude-adjusted first components from the vertical polarization channels and horizontal polarization channels are combined by a respective one of first summing nodes 414a and 414c. The first summing node 414a is configured to conduct component-wise sum of respective first components of the vertical channels. The first summing node 414c is configured to conduct component-wise sum of respective second components of the vertical channels. Similarly, the amplitude-adjusted second components from the vertical polarization channels and horizontal polarization channels are combined by a respective one of second summing nodes 414b and 414d. The second summing node 414b is configured to conduct component-wise sum of respective second components of the horizontal channels. The second summing node 414d is configured to conduct component-wise sum of respective second components of the horizontal channels. In some embodiments, the first and second summing nodes 414a, 414b, 414c, and 414d may include summing amplifiers (e.g., where RF signals are propagated as voltage signals) and/or current combiners (e.g., where RF signals are propagated as current signals).

A first I/Q generator 416a is coupled to the outputs of the respective one of the first summing node 414a and the second summing node 414b associated with the vertical polarization channels, and is configured to reconstruct the beamformed vertical polarization signal from the combined first and second components (corresponding to I and Q components). Similarly, a second I/Q generator 416b is coupled to the outputs of the respective one of the first summing node 414c and the second summing node 414d associated with the horizontal polarization channels, and is configured to reconstruct the signal of the horizontal polarization from the corresponding first and second components (corresponding to I and Q components). The outputs of the first and second I/Q generators 416a and 416b are then provided to respective polarization-specific amplification stages for further signal conditioning.

In some embodiments, the polarization combining section includes a vertical polarization variable gain amplifier (VGA_V) 418a configured to control the amplitude of the vertically polarized signal, and a horizontal polarization variable gain amplifier (VGA_H) 418b configured to control the amplitude of the horizontally polarized signal. The outputs of VGA_V 418a and VGA_H 418b are then combined by a third summing node 420 to generate a single output signal.

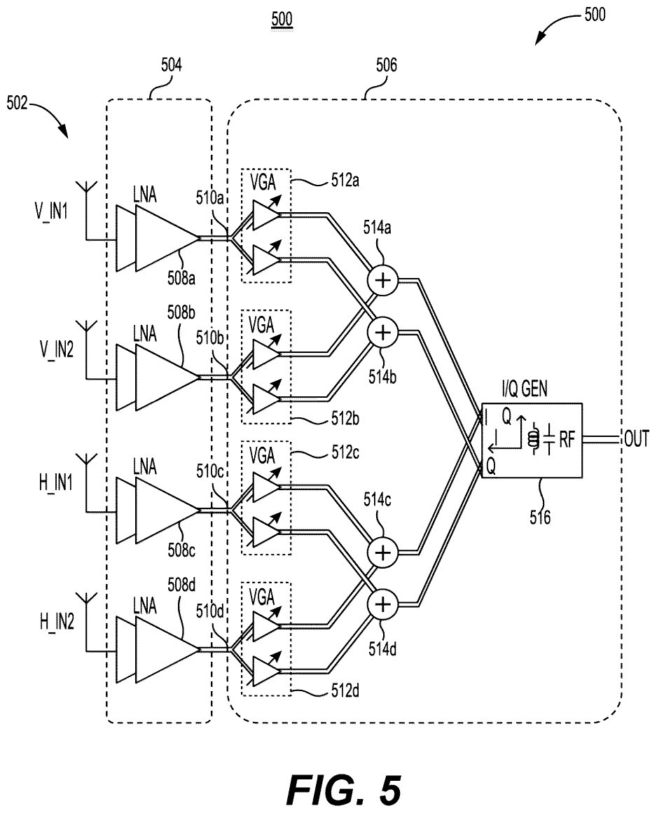

FIG. 5 is a circuit diagram of an example RF receiver system 500 that includes an I/Q generator shared among the signal channels of vertical polarization and horizontal polarization, in accordance with some embodiments of the present disclosure. As shown in FIG. 5, the system 500 includes an antenna system 502, a receive circuit 504, and a beamformer 506. Similar to FIG. 3, the system 500 employs separate signal processing channels for vertical and horizontal channel polarizations, and the antenna system 502 is configured to receive vertically polarized signals V_IN1 and V_IN2 and horizontally polarized signals H_IN1 and H_IN2.

In some embodiments, the receive circuit 504 includes receivers having respective low-noise amplifiers (LNAs) 508a, 508b, 508c, and 508d, configured to receive RF signals via antennas of the vertical polarization and horizontal polarization.

In some embodiments, the beamformer 506 is configured to perform vector modulation in a manner consistent with the embodiment illustrated in FIGS. 2A-2B. Similar to the configuration shown in FIG. 4, splitters 510a, 510b, 510c, and 510d, coupled to the antenna system 502 via LNAs 508a, 508b, 508c, and 508d, are configured to generate first components and second components (corresponding to in-phase (I) and quadrature (Q) components) from received RF signals. The first and second components are then amplitude-adjusted by vector modulator VGAs 512a, 512b, 512c, and 512d, each including an in-phase variable gain amplifier (I-VGA) and a quadrature variable gain amplifier (Q-VGA). The vector modulator VGAs 512a and 512b are associated with the vertical polarization channels, and the vector modulator VGAs 512c and 512d are associated with the horizontal polarization channels. In some embodiments, each VGA may further include switched-cascode circuitry configured to apply gain settings for the respective polarization channels and to perform polarization control on the I/Q outputs.

In some embodiments, first summing node 514a is coupled between the in-phase outputs (of first components) of the vector modulator VGAs 512a and 512b for the vertical polarization and corresponding in-phase inputs of the I/Q generator 516. First summing node 514c is coupled between the in-phase outputs (of first components) of the vector modulator VGAs 512c and 512d for the horizontal polarization, and corresponding in-phase inputs of the I/Q generator 516. Each of the first summing nodes 514a and 514c combines the amplitude-adjusted first components within its respective polarization channels. Similarly, second summing nodes 514b and 514d are coupled between the quadrature input of the I/Q generator 516 and the quadrature outputs (of the second components) of the vector modulator VGAs 512a-512b and 512c-512d, respectively, to combine the amplitude-adjusted second components for each polarization. Accordingly, the first and second summing nodes 514a-514d may be coupled between the vector modulator VGAs 512a, 512b, 512c, and 512d and the input ports of the I/Q generator 516 to perform component-wise summation of signals split by splitters 510a, 510b, 510c, and 510d.

In some implementations, the first and second summing nodes 514a-514d may include summing amplifiers and/or current combiners, depending on whether the RF signals are propagated as voltage signals or current signals.

In some embodiments, the I/Q generator 516 is coupled to the first and second summing nodes 514a-514d and is configured to receive the combined first and second components (corresponding to I and Q signal components). These combined first and second components each include contributions from both the vertical and horizontal polarization channels after gain control. In some implementations, the I/Q generator 516 performs polarization combination based on the gain-controlled vertical and horizontal polarization signals. The I/Q generator 516 functions as both a phase shifter and a combiner, processing the combined polarization signals to generate a composite output signal.

In some embodiments, the first vector modulator VGAs 512a and 512b, which correspond to the vertical polarization channel, and the second vector modulator VGAs 512c and 512d, which correspond to the horizontal polarization channel, may include shared inductive coils. For example, inductive elements that would otherwise be separately implemented in each of the vertical modulator VGAs 512a and 512b for the vertical polarization channels may instead be commonly shared, and similarly, inductive elements in the vector modulator VGAs 512c and 512d for the horizontal polarization channels may also be shared. Sharing inductive coils in this manner can reduce circuit area and component count while still providing the required inductance for impedance matching, filtering, or signal conditioning. In some implementations, the use of shared inductive coils may also improve symmetry between the polarization channels, thereby enhancing balance and reducing mismatch in the RF beamforming circuit.

In some embodiments, the I/Q generator 516 receives the combined first and second components (corresponding to I and Q signal components) from the first and second summing nodes 514a-514d through corresponding transmission lines, where each signal channel routes its processed signals to the I/Q generator 516 for final phase shifting and combining functionality.

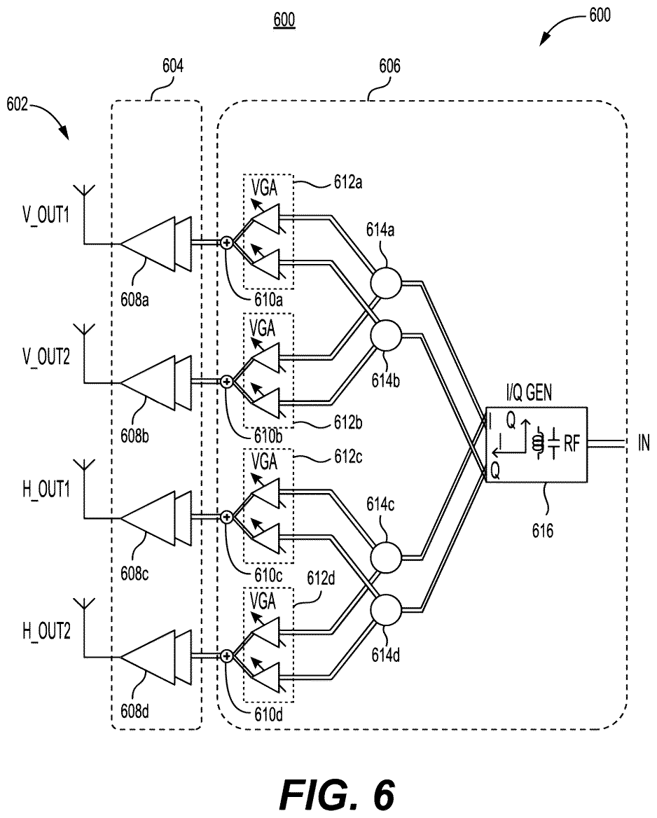

FIG. 6 is a circuit diagram of an example RF transmitter system 600 that includes an I/Q generator shared among the signal channels, in accordance with some embodiments of the present disclosure. As shown in FIG. 6, the system 600 includes an antenna system 602, a transmit circuit 604, and a beamformer 606.

In some embodiments, the system 600 employs separate signal processing channels for vertical and horizontal channel polarizations, and the antenna system 602 is configured to transmit vertically polarized signals V_OUT1 and V_OUT2 and horizontally polarized signals H_OUT1 and H_OUT2.

In some embodiments, the transmit circuit 604 includes transmitters having respective power amplifiers (PAs) 608a, 608b, 608c, and 608d, configured to transmit RF signals via antennas of the vertical polarization and horizontal polarizations.

In some embodiments, the beamformer 606 may be configured to perform vector modulation in a manner consistent with the embodiment illustrated in FIGS. 2A-2B. As shown in FIG. 6, the beamformer 606 includes first dividing nodes 614a and 614c, and second dividing nodes 614b and 614d.

In some embodiments, the first and second dividing nodes 614a, 614b, 614c, and 614d are coupled to an I/Q generator 616, which functions as a signal source for both first and second components (corresponding to I and Q signal components) of the transmit signal, and may include inductive elements shared across the transmit channels. The first and second components are subsequently distributed into vertical and horizontal polarization channels for gain control and combination. In some implementations, the I/Q generator 616 performs signal generation and phase shifting to produce the polarization signals based on the input data stream. The I/Q generator 616 functions as both a phase shifter and a splitter, generating the first and second components that are processed through the polarization channels to form a composite transmit signal.

In some embodiments, first dividing node 614a is coupled between the in-phase inputs (of first components) of vector modulation circuits 612a and 612b for the vertical polarization and corresponding in-phase outputs of the I/Q generator 616. First dividing node 614c is coupled between the in-phase inputs (of the first components) of vector modulation circuits 612c and 612d for the horizontal polarization and corresponding in-phase output of the I/Q generator 616. Each of the first dividing nodes 614a and 614c split the first components within its respective polarization channels. Similarly, second dividing nodes 614b and 614d are coupled between the quadrature output of the I/Q generator 616 and the quadrature inputs (of the second components) of the vector modulation circuits 612a-612b and 612c-612d, respectively, to split the second components within its respective polarization channels. Accordingly, the first and second dividing nodes 614a-614d are configured to perform component-wise distribution of RF signals into each transmit channel to transition the RF signals from an RF transmit signal.

In some implementations, the first and second dividing nodes 614a-614d may include power dividers and/or current dividers, depending on whether the RF signals are propagated as voltage signals or current signals.

In some embodiments, each vector modulation circuit 612a, 612b, 612c, and 612d includes an in-phase variable gain amplifier (I-VGA) and a quadrature variable gain amplifier (Q-VGA) configured to independently adjust the amplitudes of the respective first and second components (corresponding to I and Q signal components) for that transmit channel.

In some implementations, the first vector modulation circuits 612a and 612b for the vertical polarization channel and the second vector modulation circuits 612c and 612d for the horizontal polarization channel may include shared inductive coils. For example, inductive elements in the vector modulation circuits 612a and 612b for the vertical polarization channels may be implemented as shared components, and inductive elements in the vector modulation circuits 612c and 612d for the horizontal polarization channels may also be shared. Accordingly, sharing inductive coils reduces circuit complexity and chip area, while also maintaining the required inductance for signal conditioning, filtering, or impedance matching. Additionally, such sharing may improve matching between the vertical and horizontal transmit paths, thereby supporting balanced polarization performance and more accurate beamforming in the transmitted signals.

In some embodiments, the outputs of the vector modulation circuits 612a, 612b, 612c, and 612d are provided to combiners 610a, 610b, 610c, and 610d, which combine the first and second components (corresponding to I and Q signal components) for each signal channel to form modulated RF signals. These combined signals are then routed to the respective PAs 608a, 608b, 608c and 608d. In some implementations, the combiners 610a, 610b, 610c, and 610d are configured to combine signals for a given transmit channel, such that each combiner outputs a single modulated RF signal for transmission via the corresponding antenna.

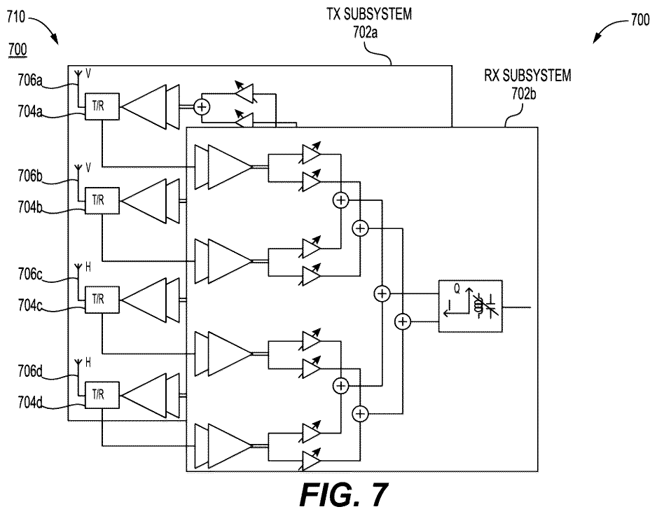

FIG. 7 is a circuit diagram of an example RF transceiver system 700 that includes a transmitter and a receiver, in accordance with some embodiments of the present disclosure. As shown in FIG. 7, the system 700 includes a transmit subsystem 702a and a receive subsystem 702b. For example, the transmit subsystem 702a may be configured in the manner describe herein for the system 600, and the receive subsystem 702b may be configured in the manner described herein for the system 500.

In some embodiments, the transmit subsystem 702a and the receive subsystem 702b share an antenna system 710. For example, the antenna system 710 includes antennas 706a, 706b, 706c, and 706d, and each transmitter of the transmit subsystem 702a may be configured to transmit RF signals via respective antennas 706a, 706b, 706c, and 706d, and each receiver of receive subsystem 702b may be configured to receive RF signals via respective antennas 706a, 706b, 706c, and 706d. In some implementations, the antenna system 710 further includes transmit/receive (T/R) switches 704a, 704b, 704c, and 704d coupled between antennas 706a, 706b, 706c, and 706d and amplifiers of the transmit subsystem 702a and receive subsystem 702b such that each antenna 706a, 706b, 706c, and 706d may operate to transmit or receive RF signals with only one subsystem at a given time.

While four antennas are described in some examples, the number of antennas is not limited to this value in other implementations. For example, some implementations may employ dozens or even hundreds of antennas for dual-polarization beamforming.

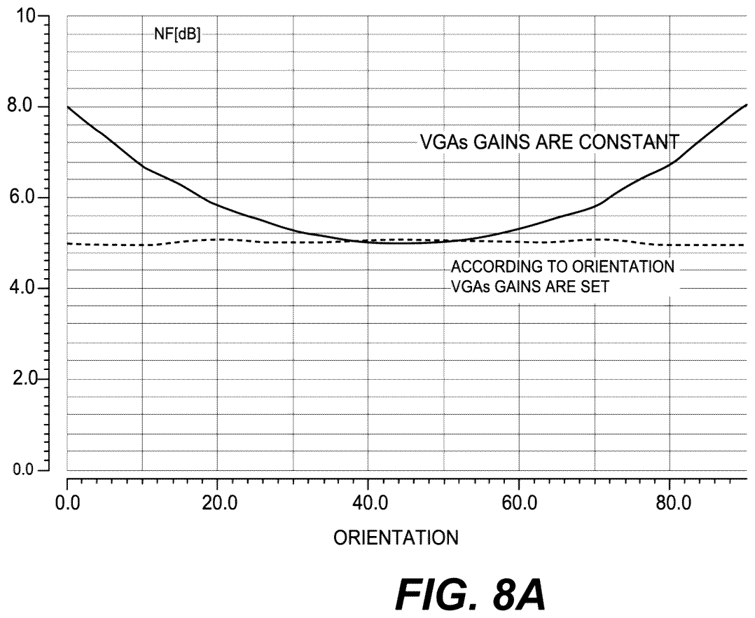

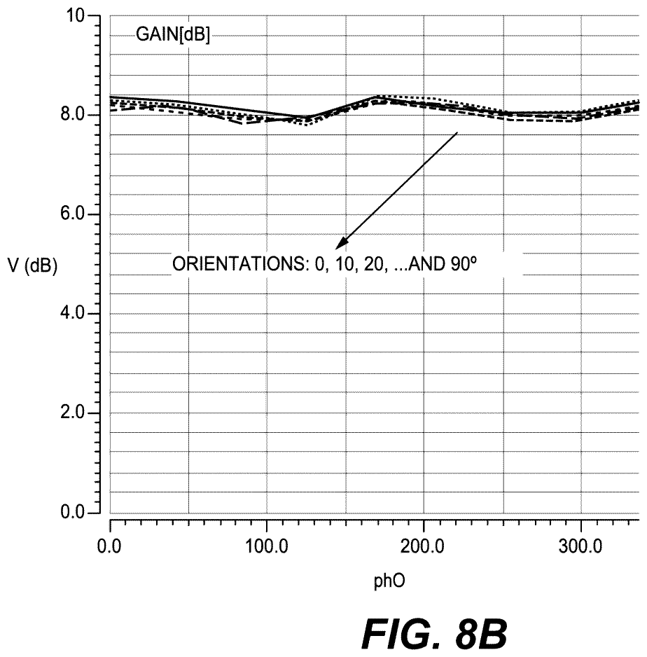

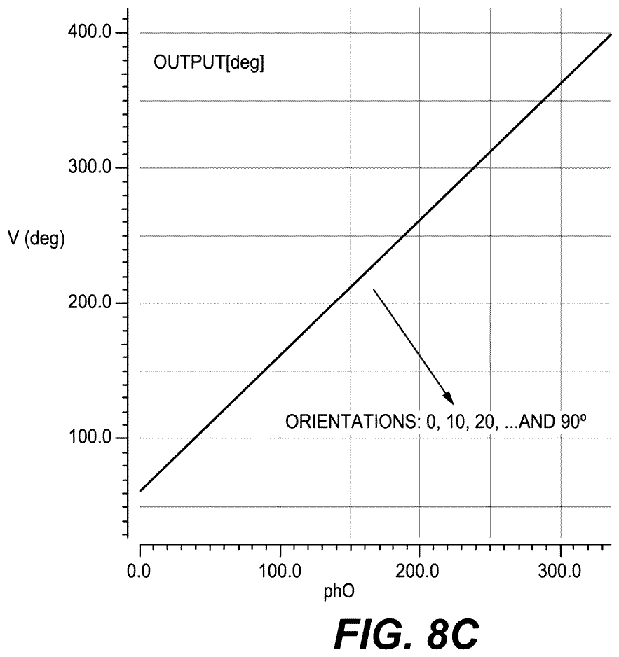

FIGS. 8A-8C illustrate performance simulation charts showing noise figure, voltage gain, and output phase characteristics of the compact dual-polarized beamforming phase shifter across varying polarization orientations ranging from 0° to 90°, in accordance with some embodiments of the present disclosure. The simulation is based on the system 500 and is conducted using linear polarization with systematic variation of polarization orientations from 0°, 10°, 20°, up to 90°, providing a comprehensive characterization of the system's performance across different polarization states.

In FIG. 8A, the noise figure (NF) plot illustrates the system 500's performance across varying polarization orientations. The lower curve indicates that a minimum NF is achieved when the gains of the variable gain amplifiers (VGAs) are adaptively controlled based on polarization orientation, demonstrating that the system can maintain favorable noise performance for each polarization state. In contrast, the upper curve shows that the NF increases when the VGA gains are held constant at 1/√2, regardless of orientation. In this scenario, the minimum noise figure occurs at a polarization orientation of 45° as expected. These results confirm that the system 500 maintains consistent noise performance while reducing component complexity compared to conventional receiver systems.

In FIG. 8B, the gain plot illustrates the beamformed gain performance of the beamformer of the system 500, showing a nearly constant voltage gain, varying by only ±0.4 dB across different input phases and polarization orientations, as the input phase is swept from 0° to 360°. This stable gain performance across the full phase range demonstrates that the proposed integrated architecture maintains consistent amplification characteristics. The minimal gain variation confirms that the use of a shared I/Q generator and integrated VGA design does not degrade the core beamforming functionality, while enabling the component reduction benefits described in this disclosure.

In FIG. 8C, the output phase plot demonstrates a linear increase in output phase with respect to the input phase settings, confirming accurate and consistent phase control across the entire operational range. This linear relationship validates that the proposed system maintains precise beamforming control, despite employing a simplified architecture with shared components. The observed linear phase response is essential for reliable beam steering functionality and confirms that the integrated design preserves the critical phase accuracy necessary for effective beamforming performance.

Therefore, the present invention provides significant advantages over conventional dual-polarized beamforming systems through its compact and integrated design approach. The proposed solution achieves substantial area reduction by leveraging shared phase shifter variable gain amplifiers that serve dual purposes for both beamforming and polarization control, utilizing shared coils between the vertical and horizontal channels, and employing a single I/Q generator instead of multiple separate units required in conventional approaches. This integration eliminates the need for additional polarization-specific VGAs and combiners, as the I/Q generator functions as the combiner itself, resulting in reduced component count, lower power consumption, minimized channel cross-talk through shared I/Q generator inductors, and simplified frequency/band calibration procedures. The invention thus overcomes the key limitations of conventional systems that require multiple I/Q generators, additional VGAs, separate combiners, and complex calibration procedures, while maintaining equivalent I/Q vector modulation performance in a significantly more space-efficient and cost-effective architecture.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A radio-frequency (RF) beamforming circuit, comprising:
amplification circuits including amplifiers configured to receive RF signals via first antennas of first polarization channels and second antennas of second polarization channels, the amplifiers each corresponding to one of the first antennas or the second antennas;
first vector modulator VGAs having first in-phase variable gain amplifiers (I-VGAs) and first quadrature variable gain amplifiers (Q-VGAs) arranged into pairs, each pair of first I-VGA and first Q-VGA being coupled to a respective one of the amplifiers that correspond to the first antennas;
second vector modulator VGAs having second I-VGAs and second Q-VGAs arranged into pairs, each pair of second I-VGA and second Q-VGA being coupled to a respective one of the amplifiers that correspond to the second antennas;
first summing nodes coupled to the first I-VGAs and the second I-VGAs, the first summing nodes configured to combine first signal components from the first I-VGAs and the second I-VGAs;
second summing nodes coupled to the first Q-VGAs and the second Q-VGAs, the second summing nodes configured to combine second signal components from the first Q-VGAs and the second Q-VGAs; and
an I/Q generator coupled to the first summing nodes and the second summing nodes.

2. The RF beamforming circuit of claim 1, wherein the I/Q generator functions as both a phase shifter for generating I/Q components and a combiner for processing the RF signals of the first polarization channels and the second polarization channels.

3. The RF beamforming circuit of claim 1, wherein the I/Q generator receives first outputs from the first summing nodes and second outputs from the second summing nodes, the first outputs corresponding to the RF signals received from both the first antennas and the second antennas, the second outputs corresponding to the RF signals received from both the first antennas and the second antennas.

4. The RF beamforming circuit of claim 1, wherein at least one of the first I-VGAs, the first Q-VGAs, the second I-VGAs, and the second Q-VGAs is configured to perform polarization gain control for the RF signals of the first polarization channels and the second polarization channels.

5. The RF beamforming circuit of claim 4, wherein the I/Q generator is configured to combine gain-controlled RF signals of the first polarization channels and the second polarization channels received from the first and second summing nodes.

6. The RF beamforming circuit of claim 1, wherein the I/Q generator is shared between the first polarization channels and the second polarization channels.

7. The RF beamforming circuit of claim 1, wherein the first vector modulator VGAs and the second vector modulator VGAs include shared inductive coils between the first polarization channels or between second polarization channels.

8. The RF beamforming circuit of claim 1, wherein the first summing nodes and second summing nodes are coupled between the first and second vector modulator VGAs and the I/Q generator.

9. The RF beamforming circuit of claim 1, wherein the first and second vector modulator VGAs are disposed to receive signals associated with the first polarization and second polarization, respectively, and each of the first and second vector modulator VGAs including transmission lines configured to route signals to a respective one of the first summing nodes or the second summing nodes.

10. The RF beamforming circuit of claim 1, wherein the beamforming circuit is integrated into a transmitter and receiver system configured for full-duplex operation with the first polarization channel and second polarization channel.

11. A radio-frequency (RF) beamforming system comprising:
first antennas and second antennas configured to receive RF signals of first polarization channels and second polarization channels, respectively;
amplification circuits configured to amplify the received RF signals, the amplification circuits having amplifiers each corresponding to one of the first antennas or the second antennas; and
a beamformer including:
first vector modulator VGAs having first in-phase variable gain amplifiers (I-VGAs) and first quadrature variable gain amplifiers (Q-VGAs) arranged into pairs, each pair of first I-VGA and first Q-VGA being coupled to a respective one of the amplifiers that correspond to the first antennas;
second vector modulator VGAs having second I-VGAs and second Q-VGAs arranged into pairs, each pair of second I-VGA and second Q-VGA being coupled to a respective one of the amplifiers that correspond to the second antennas;
first summing nodes coupled to the first I-VGAs and the second I-VGAs, the first summing nodes configured to combine first signal components from the first I-VGAs and the second I-VGAs;
second summing nodes coupled to the first Q-VGAs and the second Q-VGAs, the second summing nodes configured to combine second signal components from the first Q-VGAs and the second Q-VGAs; and
an I/Q generator coupled to the first summing nodes and the second summing nodes.

12. The RF beamforming system of claim 11, wherein the I/Q generator functions as both a phase shifter for generating I/Q components and a combiner for processing the RF signals of the first polarization channels and the second polarization channels.

13. The RF beamforming system of claim 11, wherein the I/Q generator receives first outputs from the first summing nodes and second outputs from the second summing nodes, the first outputs corresponding to the RF signals received from both the first antennas and the second antennas, the second outputs corresponding to the RF signals received from both the first antennas and the second antennas.

14. The RF beamforming system of claim 11, wherein at least one of the first I-VGAs, the first Q-VGAs, the second I-VGAs, and the second Q-VGAs is configured to perform polarization gain control for the RF signals of the first polarization channels and the second polarization channels.

15. The RF beamforming system of claim 14, wherein the I/Q generator is configured to combine gain-controlled RF signals of the first polarization channels and the second polarization channels received from the first and second summing nodes.

16. The RF beamforming system of claim 11, wherein the I/Q generator is shared between the first polarization channel and the second polarization channels.

17. The RF beamforming system of claim 11, wherein the first vector modulator VGAs and the second vector modulator VGAs include shared inductive coils between the first polarization channel and second polarization channels.

18. The RF beamforming system of claim 11, wherein the first summing nodes and second summing nodes are coupled between the first and second vector modulator VGAs and the I/Q generator.

19. The RF beamforming system of claim 11, wherein the first and second vector modulator VGAs are disposed to receive signals associated with the first polarization and second polarization, respectively, and each of the first and second vector modulator VGAs including transmission lines configured to route signals to a respective one of the first summing nodes or the second summing nodes.

20. The RF beamforming system of claim 11, wherein the beamforming circuit is integrated into a transmitter and receiver system and configured for full-duplex operation with the first polarization channel and second polarization channel.
